(19) United States
(12) Patent Application Publication
(10) Pub. No.: US 2024/0175907 A1
(43) Pub. Date: May 30, 2024

(54) DEFECT EVALUATION METHOD FOR EVALUATING DEFECT DUE TO ELECTROSTATIC DISCHARGE AND DEFECT EVALUATION DEVICE PERFORMING THE SAME

(71) Applicant: Samsung Display Co., LTD., Yongin-si (KR)

(72) Inventors: YOUNG JE CHO, Yongin-si (KR); SANG DO YU, Yongin-si (KR)

(21) Appl. No.: 18/220,879

(22) Filed: Jul. 12, 2023

(30) Foreign Application Priority Data
Nov. 30, 2022 (KR) 10-2022-0164175

(51) Int. Cl. G01R 31/00; G01R 31/319

(52) U.S. Cl. CPC G01R 31/002; G01R 31/31908; G01R 31/31917

(57) ABSTRACT

A defect evaluation method for evaluating a defect due to electrostatic discharge includes obtaining a charged map of a lower part of a test object, preparing a test pattern simulating the charged map of the lower part of the test object, contacting the test object to the test pattern, and applying a voltage to the test pattern. Accordingly, to simulate and evaluate the defect that may occur during a manufacturing process of the test object in advance. In addition, using a result obtained by the simulation and the evaluation, an arrangement of a portion vulnerable to the defect of a structure in the test object may be changed.

This application claims priority to Korean Patent Application No. 10-2022-0164175 filed on Nov. 30, 2022, and all the benefits accruing therefrom under 35 U.S.C. § 119, the content of which in its entirety is herein incorporated by reference.

### BACKGROUND

### 1. Field

This disclosure relates to a defect evaluation method for evaluating a defect due to electrostatic discharge. More particularly, this disclosure relates to a defect evaluation method for evaluating a defect due to electrostatic discharge and a defect evaluation device performing the defect evaluation method for evaluating a defect due to electrostatic discharge.

### 2. Description of the Related Art

Static electricity may be generated in various manufacturing processes of a display device. When friction occurs between two objects, one object may be positively charged and the other object may be negatively charged. When positive or negative charges are concentrated in one place, an insulator may lose or gain electrons. Accordingly, the static electricity may be generated on a surface of the insulator. For example, the static electricity may be generated in various processes such as a deposition process, a patterning process, a transfer process.

### SUMMARY

In the processes of manufacturing the display device, when a defect due to the electrostatic charge occurs, problems may occur in operation of a finished product or deterioration in the quality of the finished product.

The disclosure in an embodiment of the disclosure may provide a defect evaluation method for evaluating a defect due to electrostatic discharge.

The disclosure in another embodiment of the disclosure may provide a defect evaluation device performing the defect evaluation method for evaluating the defect due to electrostatic discharge.

The defect evaluation method for evaluating a defect due to electrostatic discharge in an embodiment of the disclosure includes obtaining a charged map of a lower part of a test object, preparing a test pattern simulating the charged map of the lower part of the test object, contacting the test object to the test pattern, and applying a voltage to the test pattern.

In an embodiment, the preparing the test pattern may include spacing a plurality of metal rods apart from each other along one direction with a predetermined interval.

In an embodiment, the applying the voltage to the test pattern may include applying the voltage to the plurality of metal rods.

In an embodiment, the preparing the test pattern may include preparing a metal plate, and forming a plurality of holes in the metal plate.

In an embodiment, the preparing the test pattern may further include disposing a metal pattern including a different type of metal from the metal plate in each of the plurality of holes. The applying the voltage to the test pattern includes applying a positive or negative voltage to the metal plate and applying a ground voltage to the metal pattern.

In an embodiment, the preparing the test pattern may further include disposing a metal pattern including a different type of metal from the metal plate in each of the plurality of holes. The applying the voltage to the test pattern includes applying a ground voltage to the metal plate and applying a positive or negative voltage to the metal pattern.

In an embodiment, the preparing the test pattern may include spacing a plurality of first metal rods apart from each other along one direction with a predetermined interval, disposing a second metal rod on one end of the plurality of first metal rods and crossing the plurality of first metal rods, connecting a resistor to the second metal rod, and connecting a ground terminal to the resistor.

In an embodiment, the applying the voltage to the test pattern may include applying the voltage to the plurality of first metal rods and the second metal rod.

In an embodiment, the contacting the test object to the test pattern may include disposing the test object between the plurality of first metal rods and the second metal rod.

In an embodiment, the applying the voltage to the test pattern may include applying the voltage to the test pattern while gradually increasing the voltage.

In an embodiment, after the applying the voltage to the test pattern, the defect evaluation method may further include detecting the defect in the test object, and separating the test object from the test pattern.

In an embodiment, the detecting the defect in the test object may include recording a defective voltage in which the defect occur in the test object.

In an embodiment, the obtaining the charged map of the lower part of the test object may include mapping contact positions between the test object and a facility used in a manufacturing process of the test object.

In an embodiment, after the separating the test object from the test pattern, the defect evaluation method may further include transforming a form of the test pattern, and contacting the test object to the test pattern again.

In an embodiment, the transforming the form of the test pattern may include rotating the test pattern by about 90 degrees.

The defect evaluation device which evaluates a defect due to electrostatic discharge in another embodiment of the disclosure includes a test pattern, a voltage supply, a detector, and an electrometer. The test pattern includes a metal. The test pattern simulates a charged map of a lower part of a test object. The voltage supply is connected to the test pattern. The detector detects the defect in the test object. The electrometer is disposed on the test object.

In an embodiment, the voltage supply may apply the voltage to the test pattern while gradually increasing the voltage.

In an embodiment, the test pattern may include a plurality of metal rods spaced apart from each other along one direction with a predetermined interval.

In an embodiment, the test pattern may include a metal plate and a metal pattern. A plurality of holes may be defined in the metal plate. The metal pattern may be disposed in each of the plurality of the holes. The metal pattern may include a different type of metal from the metal plate.

In an embodiment, the test pattern may include a plurality of first metal rods, a second metal rod, a resistor, and a ground terminal. The plurality of first metal rods may be disposed of spaced apart from each other along one direction with a predetermined interval. The second metal rod may be disposed on one end of the plurality of first metal rods and crossing the plurality of first metal rods. The resistor may be connected to the second metal rod. The ground terminal may be connected to the resistor.

The defect evaluation method for evaluating a defect due to electrostatic discharge in an embodiment of the disclosure includes obtaining a charged map of a lower part of a test object, preparing a test pattern simulating the charged map of the lower part of the test object, contacting the test object to the test pattern, and applying a voltage to the test pattern. Accordingly, in the manufacturing process of the test object, the defect due to electrostatic discharge may be simulated and evaluated in advance. In addition, an arrangement of structures (e.g., a design vulnerable to the defect) of a portion vulnerable to the defect in the test object may be changed using a simulation and evaluation result. Through this, the test object may have a more robust structure against electrostatic discharge.

In addition, in the defect evaluation method may include the applying the voltage to the test pattern while gradually increasing the voltage. Through this, an optimal process condition (e.g., constant voltage specification, etc.) for preventing occurrence of the defect in the test object may be derived.

In addition, the defect evaluation method may include the transforming the form of the test pattern. Through this, the optimal process condition (e.g., intervals between rollers, etc.) for preventing the occurrence of the defect in the test object may be derived.

### BRIEF DESCRIPTION OF THE DRAWINGS

Illustrative, non-limiting embodiments will be more clearly understood from the following detailed description in conjunction with the accompanying drawings.

FIG. 1 is a block diagram of an embodiment of the defect evaluation device which evaluates a defect due to electrostatic discharge according to the disclosure.

FIG. 2 is a view illustrating an embodiment of the defect evaluation device which evaluates a defect due to the electrostatic discharge of FIG. 1.

FIG. 3 is a flowchart illustrating an embodiment of the defect evaluation method for evaluating a defect due to electrostatic discharge according to the disclosure.

FIGS. 4, 5, 6, 7, 8, 9, and 10 are views illustrating an embodiment of the defect evaluation method for evaluating a defect due to electrostatic discharge of FIG. 3.

FIGS. 11, 12, 13, 14, and 15 are views illustrating another embodiment of the defect evaluation method for evaluating a defect due to electrostatic discharge of FIG. 3.

FIGS. 16, 17, 18, and 19 are views illustrating another embodiment of the defect evaluation method for evaluating a defect due to electrostatic discharge of FIG. 3.

### DETAILED DESCRIPTION

Hereinafter, embodiments of the disclosure will be described in more detail with reference to the accompanying drawings. The same or similar reference numerals are used for the same components in the drawings, and redundant descriptions of the same components will be omitted.

A display device capable of displaying an image may include a substrate and various thin films or devices disposed on the substrate. Electrostatic discharge may be generated in various manufacturing processes of the display device. Electrostatic discharge may be generated by roller, belt conveyance, air knife, seal ink, cleaning liquid, vacuum chuck, film detachment, or the like.

The thin films or the devices disposed on the substrate may be destroyed by the electrostatic discharge. In addition, problems such as dislocation of the substrate or scattering of the ink may occur in various manufacturing processes due to electrostatic discharge.

Models related to electrostatic discharge may be classified into a human body model (“HBM”), a machine model (“MM”), and a charged device model (“CDM”). The human body model relates to an electrostatic discharge phenomenon that may occur when a charged worker and a device contact, the machine model relates to an electrostatic discharge phenomenon that may occur when a charged machine and the device contact, and the charged device model relates to an electrostatic discharge phenomenon that may occur when a charged device is rapidly discharged.

The models related to the electrostatic discharge phenomenon may perform an electrostatic discharge tolerance evaluation by directly applying a waveform according to a defective case to the device or the like.

However, during the manufacturing process of the display device, performing the electrostatic discharge tolerance evaluation may be difficult. The defect due to the electrostatic discharge may mainly occur under the substrate. Since the substrate included in the display device is non-conductive (i.e., insulator), performing the electrostatic discharge tolerance evaluation by directly applying the waveform to the substrate may be difficult.

During the manufacturing process of the display device, the electrostatic discharge tolerance evaluation may be performed as follows. A voltage may be directly applied to one point of a metal pattern disposed on the substrate. In this case, since the defect may occur at an adjacent location instead of the one point (i.e., another point of the metal pattern), performing the electrostatic discharge tolerance evaluation accurately may be difficult.

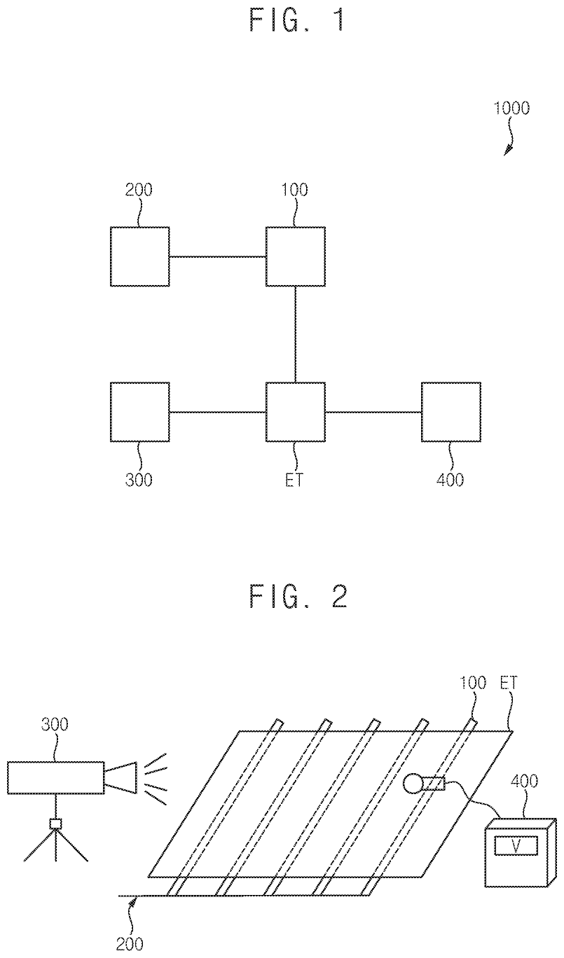

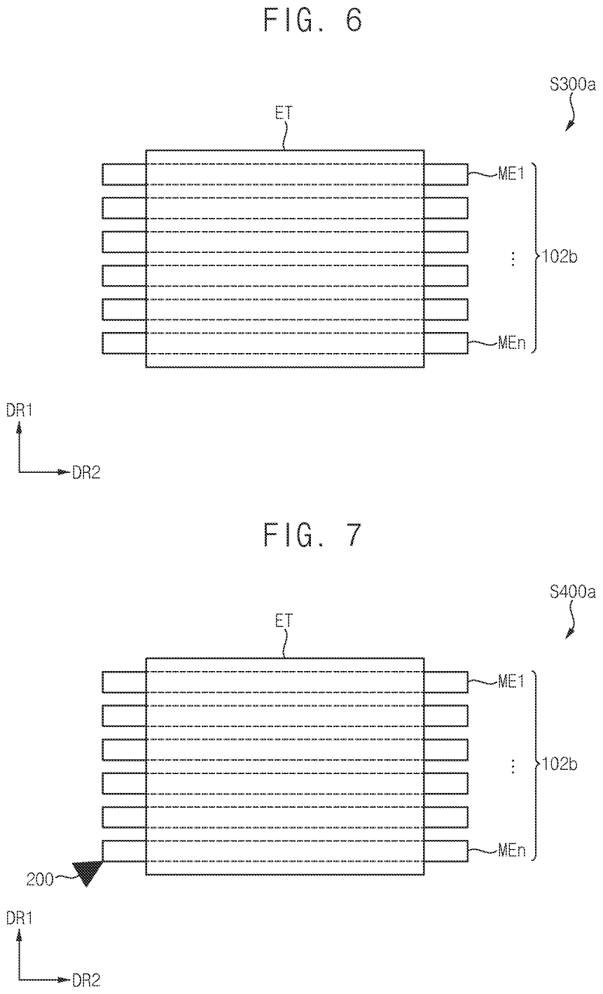

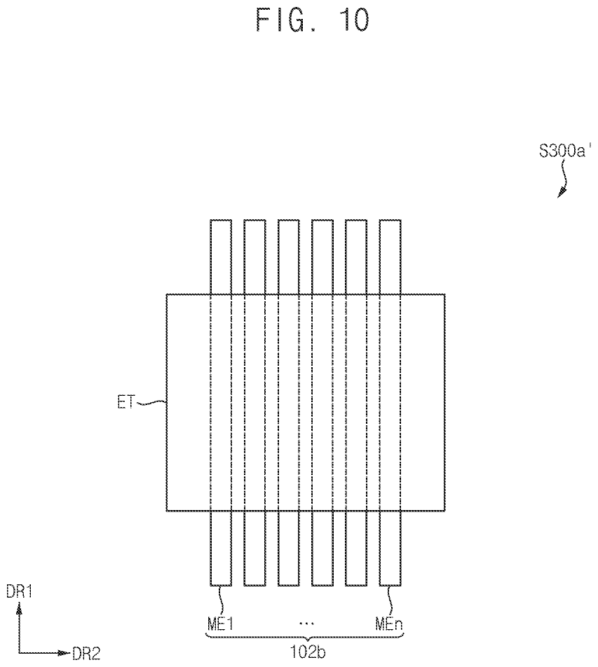

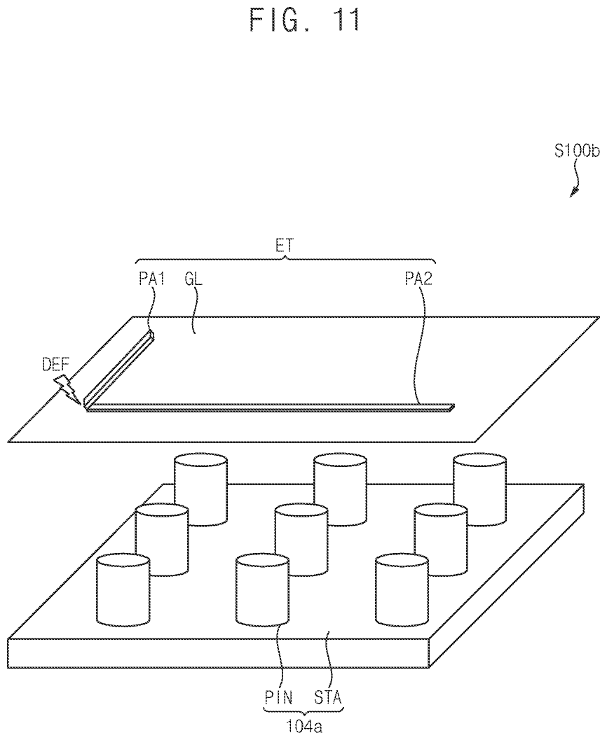

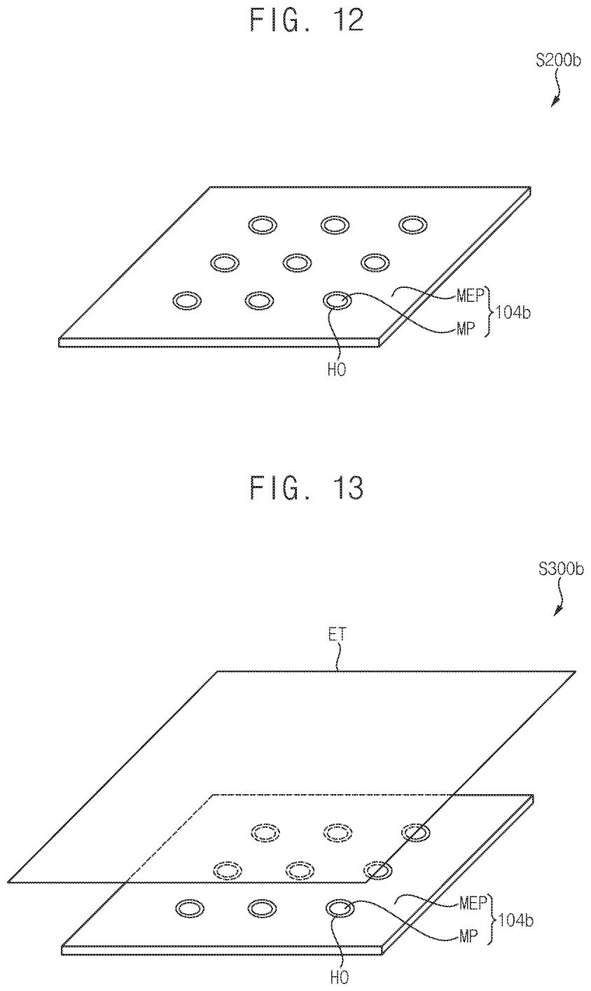

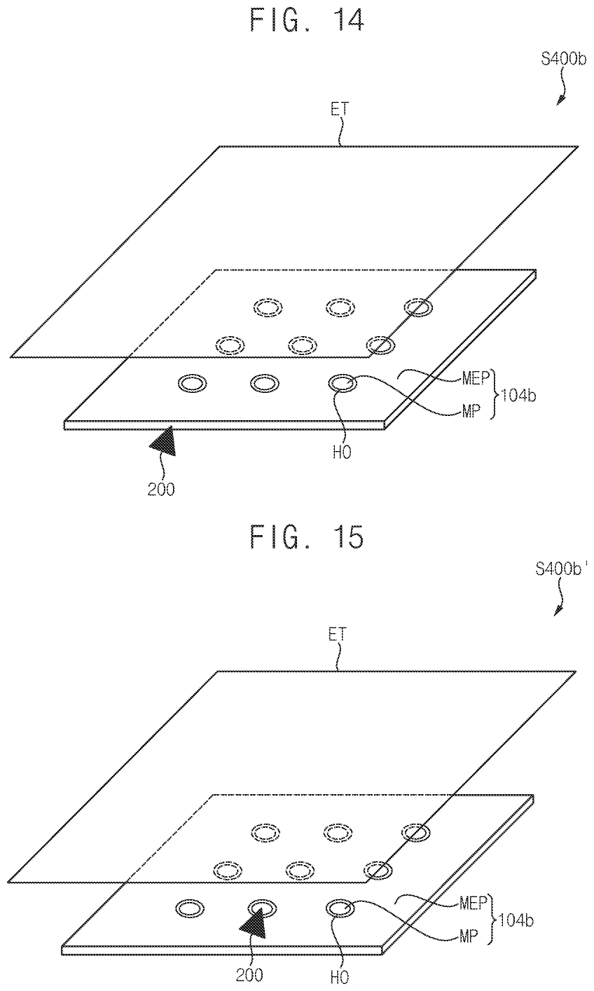

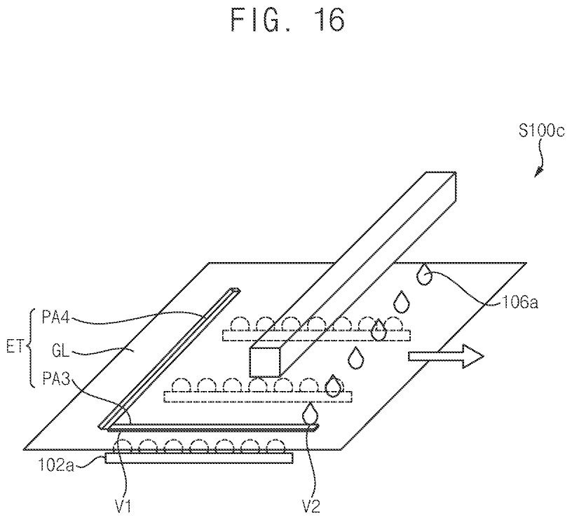

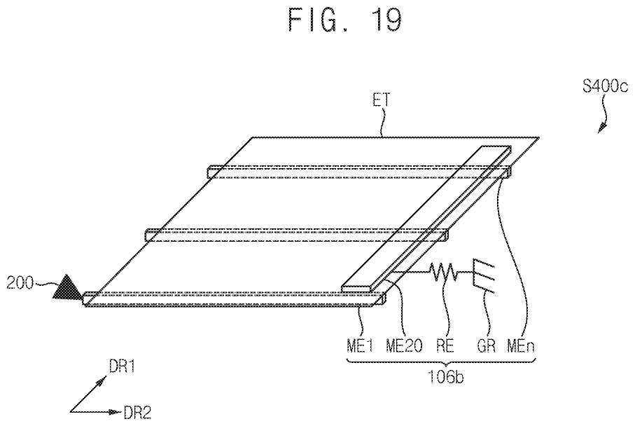

Hereinafter, a defect evaluation device 1000 which evaluates a defect due to the electrostatic discharge using a voltage gradient and a defect evaluation method 2000 for evaluating the defect due to the electrostatic discharge will be described with reference to FIGS. 1 to 19. Since the defect evaluation device 1000 which evaluates the defect due to the electrostatic discharge and the defect evaluation method 2000 for evaluating the defect due to the electrostatic discharge use the voltage gradient, the defect evaluation device 1000 which evaluates the defect due to the electrostatic discharge and the defect evaluation method 2000 for evaluating the defect due to the electrostatic discharge may simulate and evaluate various defects of a test object ET that may occur during the manufacturing process of the test object ET.

FIG. 1 is a block diagram of an embodiment of the defect evaluation device which evaluates a defect due to electrostatic discharge according to the disclosure. FIG. 2 is a view illustrating an embodiment of the defect evaluation device which evaluates a defect due to the electrostatic discharge of FIG. 1.

Referring to FIGS. 1 and 2, the defect evaluation device 1000 which evaluates the defect due to the electrostatic discharge may include a test pattern 100, a voltage supply 200, a detector 300, and an electrometer 400.

The defect evaluation device 1000 which evaluates the defect due to the electrostatic discharge may induce the defect in the test object ET by induced charging using the voltage gradient. The test object ET may be a conductor, semiconductor, or insulator. In the semiconductor or the insulator, a discharge defect may occur due to the electrostatic discharge. In the semiconductor or the conductor, a Joule heating deterioration or the like may occur due to the electrostatic discharge. In other words, the defect evaluation device 1000 which evaluates the defect due to electrostatic discharge may induce the discharge defect, the Joule heating deterioration, or the like in the test object ET by the induced charging using the voltage gradient. Through this, to simulate and evaluate various defects of the test object ET that may occur during the manufacturing process of the test object ET may be performed.

In an embodiment, the test object ET may include the substrate and a structure disposed on the substrate. The structure may include the insulator, the conductor, and/or the semiconductor.

In an embodiment, the test object ET may be the display device under manufacture or the display device that is a finished product, for example. The substrate may be a single substrate for the display device. In an alternative embodiment, the substrate may be provided in plural. The plurality of substrates may face each other. The substrate may be for a single display device. In an alternative embodiment, the substrate may be a mother glass including a plurality of unit cells.

In an embodiment, the substrate may be the insulator including glass. The insulator structure may be a thin film such as a buffer layer, for example. The conductor structure may be a line. The semiconductor structure may be an active layer included in a thin film transistor. However, the disclosure is not limited thereto, and the test object ET may include various structures such as the insulator structure, the conductor structure, and/or the semiconductor structure on the substrate.

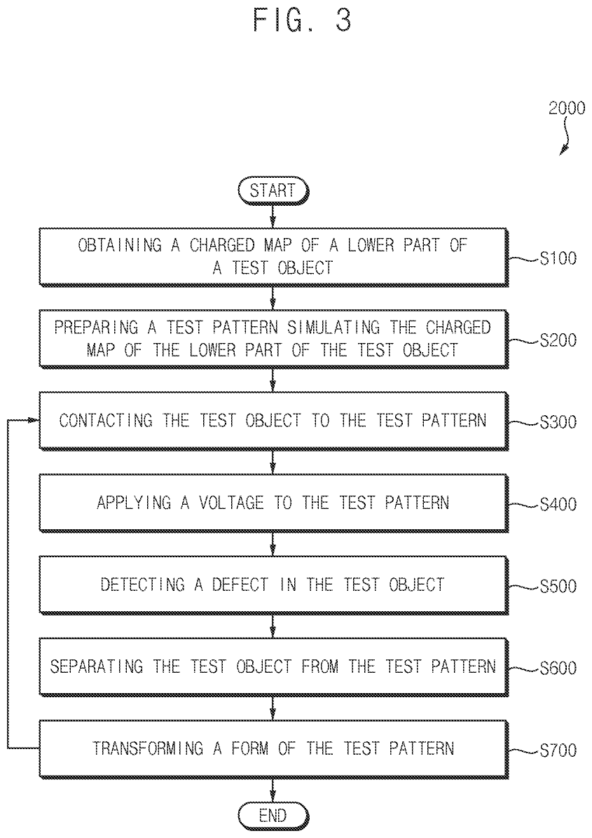

In an embodiment, the test pattern 100 may include a metal. The test pattern 100 may simulate a charged map of a lower part of the test object ET. A detailed description of a form of the test pattern 100 will be described later with reference to FIGS. 3 to 16.

In an embodiment, the voltage supply 200 may be connected to the test pattern 100. The voltage supply 200 may apply voltage to the test pattern 100. In an embodiment, the voltage supply 200 may be an electrostatic discharge gun (“ESD gun”), or the like, for example. However, the disclosure is not limited thereto, and the voltage supply 200 may be various devices capable of applying a relatively high voltage.

A potential difference may occur between an area where the test pattern 100 is disposed and an area where the test pattern 100 is not disposed. The defect (e.g., the discharge defect, the Joule heating deterioration, etc.) may be induced in the test object ET by the induced charging using the potential difference. Through this, to simulate and evaluate the various defects of the test object ET that may occur during the manufacturing process of the test object ET may be performed.

In an embodiment, the voltage supply 200 may apply the voltage to the test pattern 100 while gradually increasing the voltage. Accordingly, a voltage inducing the defect in the test object ET by induced charging (hereinafter, also referred to as “a defective voltage”) may be detected. The value of the defective voltage may be confirmed through an applied voltage of the voltage supply 200 and a measured voltage measured by the electrometer 400 described later.

The voltage supply 200 may apply the voltage to the test pattern 100 a plurality of times. In an embodiment, the voltage supply 200 may apply the voltage while transforming a form of the test pattern 100, for example. In an alternative embodiment, the voltage supply 200 may apply the voltage while changing a contact position between the test object ET and the voltage supply 200.

The detector 300 may detect the defect in the test object ET. In an embodiment, the discharge defect may occur in the insulator or the semiconductor due to the electrostatic discharge, for example. The Joule heating deterioration or the like may also occur in the semiconductor or the conductor due to the electrostatic discharge.

In an embodiment, the detector 300 may be a CoroCAM®. The CoroCAM® may be a camera capable of detecting corona discharge. When the corona discharge occurs, the CoroCAM® may detect the ultrasonic component and display the ultrasonic component as an image. Accordingly, the CoroCAM® may detect the defect in the test object ET due to the induced charging in the insulator on the substrate.

In another embodiment, the detector 300 may be a thermal imaging camera. The thermal imaging camera may detect heat generated by the generation of the electrostatic discharge. The thermal imaging camera may detect the defect in the test object ET due to the induced charge in the semiconductor on the substrate. In addition, the thermal imaging camera may detect the defect in the test object ET due to the induced charge in the conductor on the substrate. However, the disclosure is not limited thereto, and the detector 300 may be a device capable of detecting the detects in the test object ET.

In an embodiment, as shown in FIG. 2, the detector 300 may be one. In an alternative embodiment, the detector 300 may be plural.

The electrometer 400 may be disposed on the test object ET. In an embodiment, the electrometer 400 may be installed in a non-contact manner, for example. The electrometer 400) may measure the voltage supplied by the voltage supply 200. The value of the defective voltage may be confirmed through the applied voltage of the voltage supply 200 and the measured voltage of the electrometer 400 described later. By managing a line specification of the manufacturing process (e.g., a washing process, a detaching process, etc.) of the display device below the defective voltage, the defect in the test object ET by induced charging (e.g., burnt of the insulator of the semiconductor, deterioration of the conductor, etc.) may be prevented.

The defect evaluation device 1000 which evaluates the defect due to the electrostatic discharge may further include a controller and a recorder.

The controller may control an operation of each of the test pattern 100, the voltage supply 200, the detector 300, and the electrometer 400).

The recorder may record the defective voltage. In addition, the recorder may also record a pattern vulnerable to the defect (e.g., an arrangement of structure in a portion where electrification occurs due to friction, an arrangement of structure in a portion where electrification occurs due to peeling, etc.).

In a case of a method of the tolerance evaluation of electrostatic discharge directly applying the voltage to the line or the like using a pin, the defect may occur only at a point where the voltage is applied. Accordingly, the defect may be induced only in a local area of the test object ET, the only waveform according to the defective case applied to the test object ET may be observed, and the defect may be induced only at a position spaced apart from the point where the voltage is applied.

The defect evaluation device 1000 which evaluates the defect due to the electrostatic discharge in an embodiment of the disclosure may use the voltage gradient between the area where the test pattern 100 is disposed and the area where the test pattern 100 is not disposed. The voltage gradient may be increased by disposing an insulated pattern grounded with the test pattern 100 in the area where the test pattern 100 is not disposed and grounding. The defect evaluation device 1000 which evaluates the defect due to the electrostatic discharge in the an embodiment of the disclosure may confirm the defect in the test object ET in a wider area than the method of electrostatic discharge tolerance evaluation by directly applying the voltage to the line or the like using the pin.

FIG. 3 is a flowchart illustrating an embodiment of the defect evaluation method for evaluating a defect due to the electrostatic discharge according to the disclosure. Hereinafter, overlapping descriptions of the defect evaluation device 1000 which evaluates the defect due to the electrostatic discharge described above with reference to FIGS. 1 and 2 will be omitted or simplified.

Referring to FIGS. 1, 2, and 3, the defect evaluation method 2000 for evaluating the defect due to the electrostatic discharge may include obtaining a charged map of a lower part of a test object ET (S100), preparing a test pattern 100 simulating the charged map of the lower part of the test object ET (S200), contacting the test object ET to the test pattern 100 (S300), applying a voltage to the test pattern 100 (S400), detecting the defect in the test object ET (S500), separating the test object ET from the test pattern 100 (S600), and transforming a form of the test pattern 100 (S700). The defect evaluation method 2000 for evaluating the defect due to the electrostatic discharge may be performed again from contacting the test object ET to the test pattern 100 (S300) after the transforming of the form of the test pattern 100 (S700).

The defect evaluation method 2000 for evaluating the defect due to the electrostatic discharge may be performed at each manufacturing process step of the test object ET. In an embodiment, the defect evaluation method 2000 for evaluating the defect due to the electrostatic discharge may be performed for each deposition process of depositing one layer, for example. Accordingly, a design vulnerable to the defect due to the electrostatic discharge may be confirmed. By modifying the design, the test object ET may have a more robust structure. In other words, the display device may have the more robust structure against the electrostatic discharge.

In addition, the defective voltage may be confirmed through the defect evaluation method 2000 for evaluating the defect due to the electrostatic discharge. The defective voltage may be used as a constant voltage specification or the like of the process line.

In addition, the defect evaluation method 2000 for evaluating the defect due to the electrostatic discharge may be performed while the transforming of the form of the test pattern 100. Through this, a facility configuration vulnerable to the defect due to the electrostatic discharge may be confirmed. The facility configuration vulnerable to the defect due to the electrostatic discharge (e.g., the interval between the rollers) may be changed. That is, the defective voltage may be used to derive an optimal process condition. Through this, a process yield may be improved, and the display device may have the more robust structure.

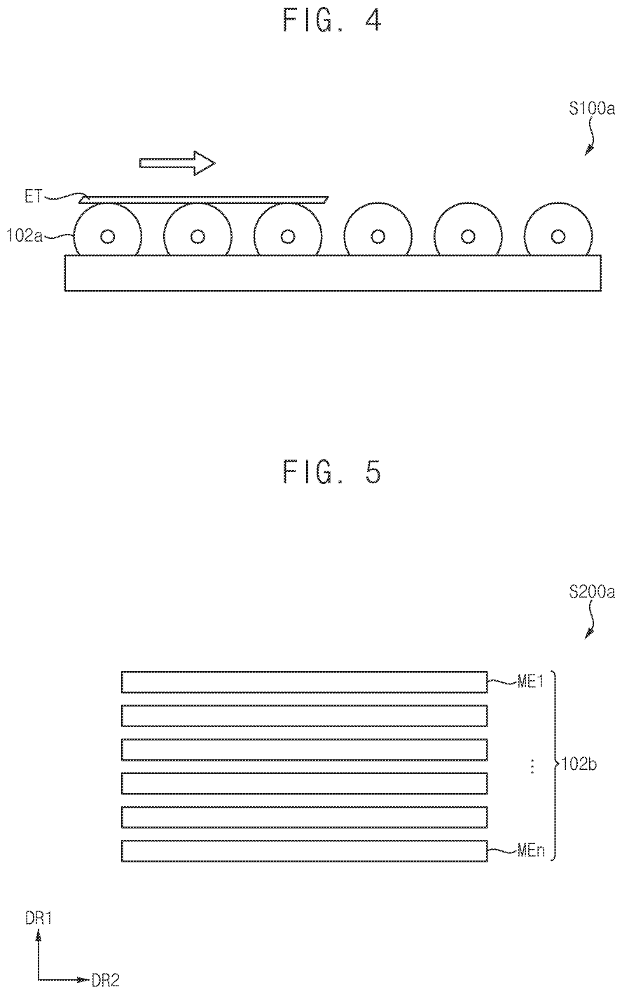

FIGS. 4, 5, 6, 7, 8, 9, and 10 are views illustrating an embodiment of the defect evaluation method for evaluating a defect due to the electrostatic discharge of FIG. 3.

Referring to FIGS. 4 and 5, the charged map of the lower part of the test object ET may be obtained (S100a), and a test pattern 102b simulating the charged map of the lower part 5 of the test object ET may be prepared (S200a).

In an embodiment, in the manufacturing process of the test object ET, contact positions between the test object ET and the facility used in the manufacturing process of the test object ET may be mapped. Accordingly, the charged map of the lower part of the test object ET may 10) be obtained. Here, the charged map of the lower part of the test object ET may be a map simulating how the lower part of the test object ET is charged in the process that the defect in the test object ET may occur. The charged map of the lower part of the test object ET may be obtained directly during the manufacturing process of the test object ET or may be obtained through a pre-stored database.

In an embodiment, when the test object ET is transported in one direction, charging may occur at contact positions between a roller 102a and the test object ET.

In a transporting process using the roller 102a, a test pattern 102b simulating the charged map of the lower part of the test object ET may include a plurality of metal rods ME1 to MEn. The plurality of metal rods ME1 to MEn may be spaced apart from each other along one direction (e.g., a first direction DR1) with a predetermined interval. Each of the plurality of metal rods ME1 to MEn may extend in a second direction DR2 crossing the first direction DR1.

Each of the plurality of metal rods ME1 to MEn may correspond to the one roller 102a.

Referring to FIGS. 1, 6, and 7, the test object ET may contact the test pattern 102b (S300a). The voltage supply 200 may apply the voltage to the test pattern 102b (S400a). The detector 300 may detect the defect of the test object ET (S500)).

In an embodiment, the test object ET may include a structure on the substrate which is the insulator, for example. The test pattern 102b may be disposed under the test object ET. In this case, since the voltage is applied to the substrate which is the insulator, the voltage may be applied to the test pattern 102b including the metal. At this time, the voltage may be applied through the voltage supply 200.

In an embodiment, the voltage may be applied to the plurality of metal rods ME1 to MEn. When the voltage is applied to the plurality of metal rods ME1 to MEn, the potential difference between an area where the plurality of metal rods ME1 to MEn is disposed and an area where the plurality of metal rods ME1 to MEn is not disposed may occur. The defect (e.g., the burnt in the insulator or the semiconductor, the deterioration in the conductor, etc.) in the test object ET by induced charge using the potential difference may occur. Through this, to simulate and evaluate the defect that may occur during the transporting process using the roller may be performed.

The voltage may be applied individually applied to each of the plurality of metal rods ME1 to MEn, or the voltage may be applied at once by connecting one end of the plurality of metal rods ME1 to MEn.

The voltage supply 200 may apply the voltage to the test pattern 102b while gradually increasing the voltage. At this time, the detector 300 may detect the defect of the test object ET. The electrometer 400 may confirm the defective voltage. As described above, the defective voltage may be a voltage value at which the defect occurs in the test object ET. When the detector 300 detects the defect in the test object ET, the electrometer 400 may confirm the defective voltage.

In an embodiment, the detecting of the defect in the test object ET (S500) may further include recording the defective voltage in which the defect occurs in the test object ET. In an embodiment, the defect evaluation method 2000 for evaluating the defect due to the electrostatic discharge may further include the recording of the defective voltage and recording the pattern vulnerable to the defect (e.g., the arrangement of structure in the portion where electrification occurs due to friction, the arrangement of structure in the portion where electrification occurs due to peeling, etc.), for example. In the step of the recording of the defective voltage, the defective voltage value and the pattern vulnerable to the defect may be recorded.

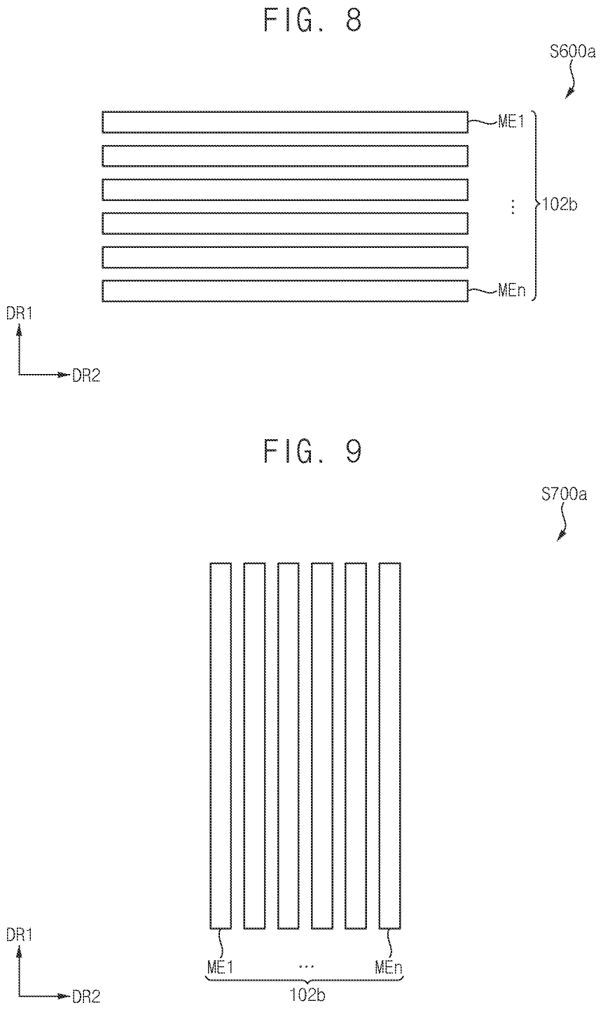

Referring to FIGS. 8, 9, and 10, the test object ET may be separated from the test pattern 102b (S600a), and then the form of the test pattern 102b may be transformed (S700a), and then the test object ET may contact again the test pattern 102b (S300a).

The defect evaluation method 2000 for evaluating the defect due to the electrostatic discharge may be performed while transforming of the form of the test pattern 102b in various ways. In an embodiment, the defect evaluation method 2000 for evaluating the defect due to the electrostatic discharge may be performed while changing size, shape, arrangement, position or the like of the test pattern 102b, for example. Specifically, the defect evaluation method 2000 for evaluating the defect due to the electrostatic discharge may be performed while adjusting the number of metal rods ME1 to MEn, a gap between the metal rods ME1 to MEn, a width of each of the metal rods ME1 to MEn or the like included in the test pattern 102b.

In an embodiment, the transforming of the form of the test pattern 102b (S700) may be a step of rotating the test pattern 102b by about 90 degrees. After the test pattern 102b is rotated by the 90 degrees, the defect evaluation method 2000 for evaluating the defect due to the electrostatic discharge may be performed again from the step of the contacting the test object ET to the test pattern 102b (S300a′). As the test pattern 102b rotates, the position in which the defect occurs in the test object ET may be changed. As described above, the defect evaluation method 2000 for evaluating the defect due to the electrostatic discharge may be performed while transforming of the form of the test pattern 102b. A result obtained by the defect evaluation method 2000 for evaluating the defect due to the electrostatic discharge may be used to derive the optimal process condition or to change the configuration of the facility of the process.

FIGS. 11, 12, 13, 14, and 15 are views illustrating another embodiment of the defect evaluation method for evaluating a defect due to the electrostatic discharge of FIG. 3. Hereinafter, overlapping descriptions of the defect evaluation device 1000 which evaluates the defect due to the electrostatic discharge and the defect evaluation method 2000 for evaluating the defect due to the electrostatic discharge described above with reference to FIGS. 3, 4, 5, 6, 7, 8, 9, and 10 will be omitted or simplified.

Referring to FIGS. 11 and 12, the charged map of the lower part of the test object ET may be obtained (S100b), and a test pattern 104b simulating the charged map of the lower part of the test object ET may be prepared (S200b).

In an embodiment, in the manufacturing process of the test object ET, the contact positions between the test object ET and the facility used in the manufacturing process of the test object ET may be mapped. Accordingly, the charged map of the lower part of the test object ET may be obtained.

In an embodiment, when the test object ET is detached from a stage STA, the charging may occur at the lower part of the test object ET. In an embodiment, a pin-up driver 104a may include the stage STA and a plurality of pins PIN, for example. The stage STA may support a substrate GL. The plurality of the pins PIN may move the substrate GL in a vertical direction from the stage STA. The test object ET may have a structure in which a first structure PA1 and a second structure PA2 are disposed on the substrate GL including a glass. In a process of the substrate GL detached from the stage STA, cap of the pins PIN may increase, and the potential difference between the first structure PA1 and the second structure PA2 may be increased. So, the defect by induced charge DEF in the test object ET may be induced. In an embodiment, the burnt or the deterioration of the first structure PA1 and the second structure PA2 or the like may occur, for example.

In an embodiment, the test pattern 104b may include a metal plate MEP in which a plurality of holes HO is defined and a metal pattern MP disposed in each of the plurality of holes HO. In an embodiment, the metal plate MEP and the metal pattern MP may include different types of metal each other, for example.

The metal pattern MP may correspond to the pin PIN, and a portion of the metal plate MEP excluding the plurality of holes HO may correspond to the stage STA.

Referring to FIGS. 1, 13, and 14, the test object ET may contact the test pattern 104b (S300b). The voltage supply 200 may apply the voltage to the test pattern 104b (S400b). The detector 300 may detect the defect of the test object ET (S500).

As the test object ET may be the insulator, the voltage may be applied to the test pattern 104b including the metal. At this time, the voltage may be applied through the voltage supply 200.

In an embodiment, a positive or negative voltage may be applied to the metal plate MEP a ground voltage may be applied to each of the metal patterns MP.

Referring to FIGS. 1, 13, and 15, the test object ET may contact the test pattern 104b (S300b). The voltage supply 200 may apply the voltage to the test pattern 104b (S400b). The detector 300 may detect the defect of the test object ET (S500).

In an embodiment, ground voltage may be applied to the metal plate MEP, and the positive or the negative voltage may be applied to each of the metal patterns MP.

When the voltage is applied only to each of the metal plate MEP or the metal pattern MP, the potential difference between an area where the plurality of the holes HO is defined and an area where the plurality of the holes HO is not defined may occur. Through the induced charging using the potential difference, to simulate and evaluate the defect that may occur during a detaching process of the substrate GL from the pin-up driver 104a may be performed.

The voltage supply 200 may apply the voltage to the test pattern 104b while gradually increasing the voltage. The detector 300 may detect the defect occurring in the test object ET. The electrometer 400 may confirm the defective voltage.

As described above with reference to FIGS. 3, 8, 9, and 10, the defect evaluation method 2000 for evaluating the defect due to the electrostatic discharge may be performed while the transforming of the form of the test pattern 104b in various ways. In an embodiment, while the transforming of type of metal included in the metal plate MEP or the metal pattern MP, size of the metal plate MEP, positions where the plurality of holes HO is defined, size of the plurality of holes HO, size of the metal pattern MP or the like, various defect that may occur during the manufacturing process of the test object ET may be simulated and evaluated, for example.

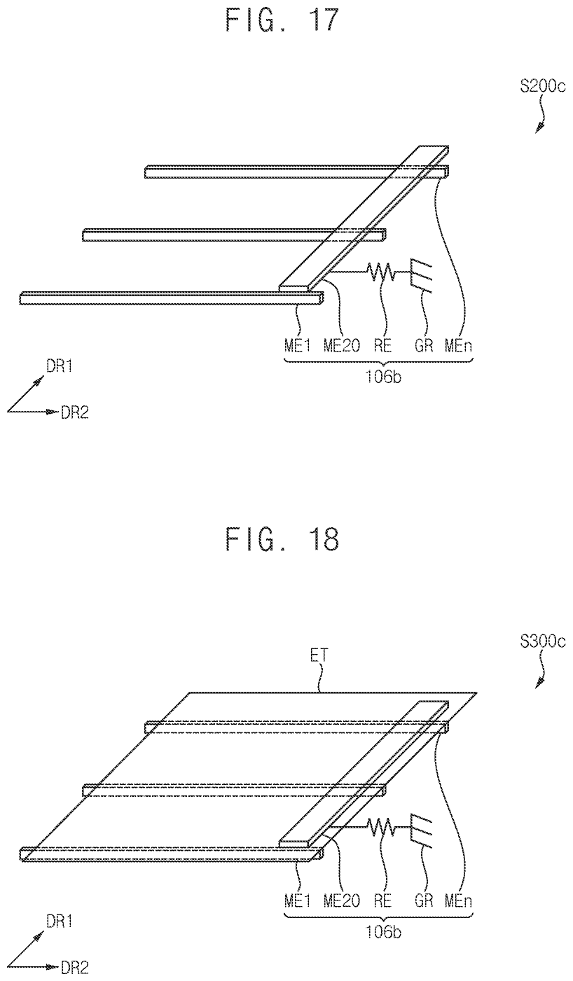

FIGS. 16, 17, 18, and 19 are views illustrating another embodiment of the defect evaluation method for evaluating a defect due to the electrostatic discharge of FIG. 3. Hereinafter, overlapping descriptions of the defect evaluation device 1000 which evaluates the defect due to the electrostatic discharge and the defect evaluation method 2000 for evaluating the defect due to the electrostatic discharge described above with reference to FIGS. 3, 4, 5, 6, 7, 8, 9, 10, 11, 12, 13, 14, and 15 will be omitted or simplified.

Referring to FIGS. 16 and 17, the charged map of the lower part of the test object ET may be obtained (S100c), and a test pattern 106b simulating the charged map of the lower part of the test object ET may be prepared (S200c).

In an embodiment, in the manufacturing process of the test object ET, the contact positions between the test object ET and the facility used in the manufacturing process of the test object ET may be mapped. Accordingly, the charged map of the lower part of the test object ET may be obtained.

In an embodiment, when the test object ET transported by the roller 102a contacts a liquid 106a, rapid discharge may occur. In an embodiment, the liquid 106a may be deionized (“DI”) water, for example. The test object ET may have a structure in which a third structure PA3 and a fourth structure PA4 are disposed on the substrate GL. The potential difference between an area V2 where the third structure PA3 contacts the liquid 106a and an area V1 where the third structure PA3 does not contact the liquid 106a may occur. Accordingly, in the test object ET, the defect by induced charge (e.g., the burnt of the insulator or the semiconductor, the deterioration of the conductor, etc.) may be induced.

The test pattern 106b may include a plurality of first metal rods ME1 to MEn, a second metal rod ME20, a resistor RE, and a ground terminal GR.

The plurality of first metal rods ME1 to MEn may be spaced apart from each other along one direction (e.g., the first direction DR1) with a predetermined interval. Each of the plurality of metal rods ME1 to MEn may extend in the second direction DR2 crossing the first direction DR1.

The second metal rod ME20 may be disposed on one end of the plurality of first metal rods ME1 to MEn and crossing the plurality of first metal rods ME1 to MEn. The second metal rod ME20 may extend in the first direction DR1. The second metal rod ME20 may connect to the resistor RE and the ground terminal GR.

Each of the plurality of first metal rods ME1 to MEn may correspond to the one roller 102a, and a portion where the resistor RE and the ground terminal GR are connected to the second metal rod ME20 may correspond to a portion in contact with the liquid 106a. In an embodiment, when simulating the DI water, a resistance value of the resistor RE may be about 10 ohm (92), for example.

Referring to FIGS. 1, 18, and 19, the test object ET may contact the test pattern 106b (S300c). The voltage supply 200 may apply the voltage to the test pattern 106b (S400c). The detector 300 may detect the defect in the test object ET (S500).

In an embodiment, in order to simulate and evaluate the rapid discharge, the test object ET may be disposed between the plurality of first metal rods ME1 to MEn and the second metal rod ME20. That is, a contact portion between the plurality of first metal rods ME1 to MEn and the test object ET may simulate charging of the test object ET by the roller 102a, and a contact portion between the second metal rod ME20 and the test object ET may simulate an occurrence of the rapid discharge by contacting with the liquid 106a and the test object ET.

As the test object ET may be the insulator, the voltage may be applied to the test pattern 106b including the metal. At this time, the voltage may be applied through the voltage supply 200.

In an embodiment, the voltage may be applied to the plurality of first metal rods ME1 to MEn and the second metal rod ME20. When the voltage is applied to the plurality of first metal rods ME1 to MEn and the second metal rod ME20, the potential difference between an area where the second metal rod ME20 is disposed and an area where the second metal rod ME20 is not disposed may occur. Through the induced charge using the potential difference, to simulate and evaluate the defect (e.g., the burnt of the insulator or the semiconductor, the deterioration of the conductor, etc.) that may occur in a washing process during the transporting process using the roller may be performed.

The voltage supply 200 may apply the voltage to the test pattern 106b while gradually increasing the voltage. The detector 300 may detect the defect occurring in the test object ET. The electrometer 400 may confirm the defective voltage at which the defect occurs.

As described above with reference to FIGS. 3, 8, 9, and 10, the defect evaluation method 2000 for evaluating the defect due to the electrostatic discharge may be performed while the transforming of the form of the test pattern 106b in various ways. In an embodiment, the defect evaluation method 2000 for evaluating the defect due to the electrostatic discharge may be performed while the transforming of the number of the plurality of metal rods ME1 to MEn, a width of the second metal rod ME20, a position of the second metal rod ME20, the resistance value of the resistor RE or the like, for example.

As described above, the defect evaluation device 1000 which evaluates the defect due to the electrostatic discharge in an embodiment of the disclosure may include the test pattern 100, 102b. 104b, and 106b simulating the charged map of the lower part of the test object ET. In the above, a case in which the test pattern 102b. 104b, and 106b simulating the charged map of the lower part of the test object ET, which may be induced in the transportation process using the roller, the detaching process form the stage, and the washing process, was taken in an embodiment. However, the disclosure is not limited thereto, and the test pattern 100 may have various forms. In an embodiment, the test pattern 100 may simulate the charged map of the lower part of the test object ET in various forms, for example. The charged map of the lower part of the test object ET may have various forms during various processes such as film peeling, rubbing or the like, and the test pattern 100 may have various forms by being manufactured in the same form as the charged map of the lower part of the test object ET. That is, the test pattern 100 may have various forms to simulate and evaluate the defect of the test object ET that may occur during the manufacturing process of the test object ET. Accordingly, the defect that may occur due to the electrostatic discharge during the manufacturing process may be simulated and evaluated. Through this, the optimal process condition (e.g., the constant voltage level) for preventing the occurrence of the defect in the test object ET may be derived. In addition, the arrangement of the structure (e.g., the line, the thin film transistor, etc.) in areas vulnerable to the defect in the test object ET may be changed by the result obtained by the simulation and the evaluation. Through this, the test object ET may have the more robust structure.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the disclosure. Accordingly, all such modifications are intended to be included within the scope of the disclosure. Therefore, it is to be understood that the foregoing is illustrative of various embodiments and is not to be construed as limited to the illustrative embodiments disclosed, and that modifications to the disclosed embodiments, as well as other embodiments, are intended to be included within the scope of the disclosure.

The disclosure may be applied to a manufacturing process of various display devices that may include a display apparatus. In an embodiment, the disclosure may be applied to the manufacturing process of high-resolution smartphones, mobile phones, smart pads, smart watches, tablet personal computers (“PCs”), vehicle navigation systems, televisions, computer monitors, laptops, or the like, for example.

What is claimed is:

1. A defect evaluation method for evaluating a defect due to electrostatic discharge, the defect evaluation method comprising:
obtaining a charged map of a lower part of a test object;
preparing a test pattern simulating the charged map of the lower part of the test object;
contacting the test object to the test pattern; and
applying a voltage to the test pattern.

2. The defect evaluation method of claim 1, wherein the preparing the test pattern includes:
spacing a plurality of metal rods apart from each other along one direction with a predetermined interval.

3. The defect evaluation method of claim 2, wherein the applying the voltage to the test pattern includes:
applying the voltage to the plurality of metal rods.

4. The defect evaluation method of claim 1, wherein the preparing the test pattern includes:
preparing a metal plate; and
forming a plurality of holes in the metal plate.

5. The defect evaluation method of claim 4, wherein the preparing the test pattern further includes:
disposing a metal pattern including a different type of metal from the metal plate in each of the plurality of holes, and
wherein the applying the voltage to the test pattern includes:
applying a positive or a negative voltage to the metal plate; and
applying a ground voltage to the metal pattern.

6. The defect evaluation method of claim 4, wherein the preparing the test pattern further includes:
disposing a metal pattern including a different type of metal from the metal plate in each of the plurality of holes, and
wherein the applying the voltage to the test pattern includes:
applying a ground voltage to the metal plate; and
applying a positive or a negative voltage to the metal pattern.

7. The defect evaluation method of claim 1, wherein the preparing the test pattern includes:
spacing a plurality of first metal rods apart from each other along one direction with a predetermined interval;
disposing a second metal rod on one end of the plurality of first metal rods to crossing the plurality of first metal rods;
connecting a resistor to the second metal rod; and
connecting a ground terminal to the resistor.

8. The defect evaluation method of claim 7, wherein the applying the voltage to the test pattern includes:
applying the voltage to the plurality of first metal rods and the second metal rod.

9. The defect evaluation method of claim 7, wherein the contacting the test object to the test pattern includes:
disposing the test object between the plurality of first metal rods and the second metal rod.

10. The defect evaluation method of claim 1, wherein the applying the voltage to the test pattern includes:
applying the voltage to the test pattern while gradually increasing the voltage.

11. The defect evaluation method of claim 1, after the applying the voltage to the test pattern, further comprising:
detecting the defect in the test object; and
separating the test object from the test pattern.

12. The defect evaluation method of claim 11, wherein the detecting the defect in the test object includes:
recording a defective voltage in which the defect occurs in the test object.

13. The defect evaluation method of claim 1, wherein the obtaining the charged map of the lower part of the test object includes:
mapping contact positions between the test object and a facility used in a manufacturing process of the test object each other.

14. The defect evaluation method of claim 11, after the separating the test object from the test pattern, further comprising:
transforming a form of the test pattern; and
contacting the test object to the test pattern again.

15. The defect evaluation method of claim 14, wherein the transforming the form of the test pattern includes:
rotating the test pattern by about 90 degrees.

16. A defect evaluation device which evaluates a defect due to electrostatic discharge, the defect evaluation device comprising:
a test pattern which simulates a charged map of a lower part of a test object, and includes a metal;
a voltage supply connected to the test pattern;
a detector which detects the defect in the test object; and
an electrometer disposed on the test object.

17. The defect evaluation device of claim 16, wherein the electrometer applies the voltage to the test object while gradually increasing the voltage.

18. The defect evaluation device of claim 16, wherein the test pattern includes:
a plurality of metal rods spaced apart from each other along one direction with a predetermined interval.

19. The defect evaluation device of claim 16, wherein the test pattern includes:
a metal plate in which a plurality of holes is defined; and
a metal pattern disposed in each of the plurality of holes, and including a different type of metal from the metal plate.

20. The defect evaluation device of claim 16, wherein the test pattern includes:
a plurality of first metal rods spaced apart from each other along one direction with a predetermined interval;
a second metal rod disposed on one end of the plurality of first metal rods and crossing the plurality of first metal rods;
a resistor connecting to the second metal rod; and
a ground terminal connecting to the resistor.
